(19) United States
(12) Patent Application Publication
(10) Pub. No.: US 2016/0040023 A1
(43) Pub. Date: Feb. 11, 2016

(54) Ink Composition for Forming Transparent Conductive Film, Transparent Conductive Film, Method for Producing Transparent Electrode, and Image Display Device

(71) Applicant: Dexerials Corporation, Shinagawa-ku, Tokyo (JP)

(72) Inventors: Yasuhisa ISHII, Utsunomiya-shi, Tochigi (JP); Mikihisa MIZUNO, Sendai-shi, Miyagi (JP); Junichi INOUE, Sendai-shi, Miyagi (JP); Naoto KANEKO, Sendai-shi, Miyagi (JP)

(73) Assignee: Dexerials Corporation, Shinagawa-ku, Tokyo (JP)

(21) Appl. No.: 14/782,634

(22) PCT Filed: Apr. 2, 2014
(86) PCT No.: PCT/JP2014/060235

§ 371 Date: Oct. 6, 2015

(30) Foreign Application Priority Data
Apr. 10, 2013 (JP) 2013-082291
Jul. 11, 2013 (JP) 2013-145834

(51) Int. Cl. C09D 11/52; G02F 1/1333; G02F 1/1343; G03F 7/20; H01B 1/02

(52) U.S. Cl. CPC C09D 11/52; G03F 7/20; H01B 1/02; G02F 1/13439; G02F 1/13338

(57) ABSTRACT

For transparent electrodes formed by using a metal nanowire-based transparent conductive film, accomplished are simplification of processes necessary in patterning the transparent conductive film and improvement in patterning accuracy of the transparent electrodes formed by using the transparent conductive film. An ink for forming the transparent conductive film used for the transparent electrodes having a distance between the electrodes of 20 μm or more contains: metal nanowires, a photosensitive material; and a solvent. The metal nanowires have an average length of 1.5 times or less the distance between the electrodes.

### TECHNICAL FIELD

The present disclosure relates to a transparent conductive film containing metal nanowires, an ink composition for foaming the transparent conductive film, a method for producing transparent electrodes by using the ink composition, and an image display device including the transparent conductive film.

### BACKGROUND

Transparent conductive films have been used, for example, in image display devices, such as a liquid crystal display and a plasma display, and touch panels configured to display images and to serve as information input devices.

An example method for forming a transparent conductive film into a predetermined pattern includes: preparing a composition for forming the film, the composition containing metal nanowires, an amide compound, a (meth)acryloyl compound, a solvent, and a photopolymerizer; applying the prepared composition onto a substrate; drying the applied composition; photoexposing the dried composition through a photomask; and developing the photoexposed composition (Refer to Patent Literature 1). Another example method includes; forming a transparent conductive film by using a dispersion liquid including metal nanowires to which colored compounds are adsorbed, a resin material, and a solvent that are dispersed therein; and patterning the formed transparent conductive film (Refer to Patent Literature 2). However, these methods each involve, for patterning the transparent conductive film, first applying a photoresist onto the transparent conductive film and then patterning the photoresist and thus require many processes for the patterning of the transparent conductive film. Besides, each method poses a risk of short-circuiting the electrodes depending on blank gap in the electrode pattern formed by using the transparent conductive film.

### CITATION LIST

### Patent Literatures

### Patent Literature 1: Japanese Patent Application Publication No. 2012-9383

### Patent Literature 2: Japanese Patent No. 4893867

### SUMMARY

### Technical Problem

In contrast to the aforementioned conventional techniques, the present disclosure is to provide an ink composition that, when transparent electrodes are produced by patterning a metal nanowire-based transparent conductive film, is capable of simplifying processes necessary in the patterning and is also capable of improving patterning accuracy. The present disclosure is also to provide a transparent conductive film formed by using such an ink composition, and an image display device including such transparent electrodes.

### Solution to Problem

The present inventors have found that, when forming a metal nanowire-based transparent conductive film and patterning the formed transparent conductive film to produce transparent electrodes having a predetermined distance between the electrodes, patterning accuracy of the transparent conductive film is improved by regulating an average length of the metal nanowires in accordance with the desired distance between the transparent electrodes, thus having completed the present disclosure.

According to one aspect, the present disclosure provides an ink composition for forming a transparent conductive film used for transparent electrodes having a distance between the electrodes of 20 μm or more. The ink composition contains: metal nanowires; a photosensitive material; and a solvent, wherein the metal nanowires have an average length of 1.5 times or less the distance between the electrodes.

Herein, the “distance between the electrodes” refers to the nearest neighbor distance between two adjacent transparent electrodes arranged in a transparent electrode pattern formed by patterning the transparent conductive film. Examples of the transparent electrode pattern include a linear pattern, a diamond pattern, and an invisible dummy pattern arranged in an insulating portion.

According to another aspect, the present disclosure provides an ink composition for forming a transparent conductive film used for transparent electrodes having a distance between the electrodes of less than 20 μm. The ink composition contains: metal nanowires; a photosensitive material; and a solvent, wherein the metal nanowires have an average length of 5 μm or more and 0.5 times or less the distance between the electrodes.

The present inventors have also found that, when forming a metal nanowire-based transparent conductive film and producing transparent electrodes by patterning the formed transparent conductive film, patterning accuracy of the transparent conductive film is improved by specifying the photosensitive material. By doing so, curing reactivity is improved mainly owing to the unsusceptibility to reaction inhibition by oxygen and the excellent solvent resistance, hardness, and scuff resistance of the cured film. Thus, the present inventors have completed the present disclosure.

Thus, according to yet another aspect, the present disclosure provides an ink composition for forming a transparent conductive film used for transparent electrodes. The ink composition contains: metal nanowires; a photosensitive material; and a solvent, wherein the photosensitive material includes a compound containing at least one of an azide group and a diazirine group.

According to yet another aspect, the present disclosure provides an ink composition for forming a transparent conductive film used for transparent electrodes having a distance between the electrodes of 20 μm or more. The ink composition contains: metal nanowires; a photosensitive material; and a solvent, wherein the metal nanowires have an average length of 1.5 times or less the distance between the electrodes, and the photosensitive material includes a polymer containing, in at least one of a main chain and a side chain thereof, at least one of an azide group and a diazirine group. The polymer containing, in at least one of the main chain and the side chain thereof, at least one of the azide group and the diazirine group is of the following general formula (I):

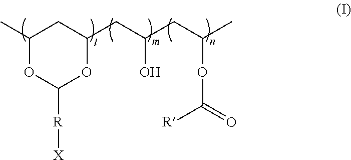

wherein, X represents one or more photosensitive groups containing at least one of the azide group and the diazirine group; R represents one of a chain or cyclic alkylene group and a derivative thereof and may contain, in at least one of a main chain and a side chain thereof, one or more of an unsaturated bond, an ether bond, a carbonyl bond, an ester bond, an amide bond, an urethane bond, a sulfide bond, an aromatic ring, a heterocyclic ring, an amino group, and a quaternary ammonium base; R′ represents one of a chain or cyclic alkyl group and a derivative thereof and may contain, in at least one of a main chain and a side chain thereof, one or more of an unsaturated bond, an ether bond, a carbonyl bond, an ester bond, an amide bond, an urethane bond, a sulfide bond, an aromatic ring, a heterocyclic ring, an amino group, and a quaternary ammonium base; and the number of a repeating unit 1 is 1 or more, the number of a repeating unit m is 1 or more, and the number of a repeating unit n is 0 or more.

Preferably, the present disclosure provides the aforementioned ink composition, further containing: colored compounds. The present disclosure also provides a transparent conductive film that is a cured product of the ink composition, wherein the colored compounds are substantially adsorbed to the metal nanowires.

According to yet another aspect, the present disclosure provides a method for producing transparent electrodes having a predetermined distance between the electrodes. The method includes: forming, on a substrate, a film of the aforementioned ink composition; pattern exposing the formed film; and developing the pattern exposed film.

According to yet another aspect, the present disclosure provides an image display device, including: an image display panel; and electrodes formed on a display surface side of the image display panel and by using a transparent conductive film, wherein the transparent conductive film is a cured product of the aforementioned ink composition.

### Advantageous Effects

Since the ink composition according to the present disclosure regulates the length of the metal nanowires in accordance with the distance between the transparent electrodes formed by using the ink composition, the electrode pattern of the transparent electrodes is defined with high precision. This prevents short circuit between the electrodes.

Furthermore, since the photosensitive material contained in the ink composition according to the present disclosure includes a compound containing at least one of the azide group and the diazirine group, curing reactivity is improved mainly owing to the unsusceptibility to reaction inhibition by oxygen and the excellent solvent resistance, hardness, and scuff resistance of the cured film. As a result, patterning accuracy of the transparent conductive film is improved.

In one embodiment of the transparent conductive film according to the present disclosure formed by using the ink composition according to the present disclosure in which the colored component is substantially adsorbed to the metal nanowires, the metal nanowires are prevented from causing diffuse reflection of natural light. Accordingly, the use of the transparent conductive film in the image display panel prevents occurrence of a “black floating phenomenon” in the image display panel.

### BRIEF DESCRIPTION OF THE DRAWING

In the accompanying drawings:

FIG. 1 is a production flow chart of transparent electrodes according to an embodiment;

FIG. 2A is a schematic view illustrating a layer structure of a touch panel;

FIG. 2B is a schematic view illustrating a layer structure of another touch panel;

FIG. 2C is a schematic view illustrating a layered structure of yet another touch panel;

FIG. 2D is a schematic view illustrating a layered structure of yet another touch panel;

FIG. 3 is a micrograph of a photomask used in one embodiment;

FIG. 4 is an electron micrograph of transparent electrodes according to one embodiment; and

FIG. 5 is a micrograph (at a magnification of 500 times) of transparent electrodes according to one embodiment.

### DETAILED DESCRIPTION

Embodiments of the present disclosure will be described in detail below with reference to the drawings. Throughout the drawings, the same reference numerals denote the same or corresponding elements.

### (1) Ink Composition for Forming Transparent Conductive Film

An ink composition for forming a transparent conductive film according to the present disclosure contains metal nanowires, a photosensitive material, and a solvent. The ink composition may be applied onto a surface of a transparent substrate or the like as a film and patterned into predetermined electrode shapes to be used as transparent electrodes. As described later below, the patterning is accomplished by pattern exposure, development, cleaning, and drying performed in the stated order. Preferably, the ink composition also contains colored compounds that may adsorb to the metal nanowires, with the colored compounds being adsorbed or unadsorbed.

### (1-1) Components of Ink Composition

### (1-1-1) Metal Nanowires

The metal nanowires contained in the ink composition according to the present disclosure are made of at least one metal selected from the group consisting of Ag, Au, Ni, Cu, Pd, Pt, Rh, Ir, Ru, Os, Fe, Co, and Sn.

The metal nanowires have shapes with an average diameter preferably in the range from 1 to 500 nm. The average diameter of 1 nm or less might deteriorate conductivity of the metal nanowires, thereby making it difficult for the applied ink composition to serve as a conductive layer. On the other hand, the average diameter of 500 nm or more might decrease total light transmittance of the transparent conductive layer, possibly resulting in an increase in haze.

The metal nanowires have an average length that may be varied in accordance with a distance between the transparent electrodes produced by using the ink composition according to the present disclosure. When the desired distance between the electrodes is 20 μm or more, the average length of the metal nanowires is set to be 1.5 times or less, preferably 1.2 times or less, more preferably 1 times or less, and even more preferably 0.5 times or less, the distance between the electrodes and also set to be within the range preferably from 5 μm to 50 μm. When the distance between the electrodes is less than 20 μm, the average length of the metal nanowires is set to be 5 μm or more and 0.5 times or less the distance between the electrodes. That is to say, although a resolution is decreased as the average length of the metal nanowires is increased and is increased as the average length of the metal nanowires is decreased, the required resolution is eased in accordance with an increase in the distance between the electrodes. Furthermore, if the distance between the electrodes is set too small, there is a risk that short circuit may occur between the electrodes due to some of the metal nanowires that lie outside the electrode pattern. On the other hand, if the average length of the metal nanowires is excessively small, the transparent conductive film formed by using the ink composition is less likely to form a network of metal nanowires contacting each other, leading to a decrease in conductivity. For these reasons, the lower limit of the average length of the metal nanowires is set to be 5 μm from the viewpoint of conductivity, and the upper limit is varied in accordance with the desired distance between the transparent electrodes produced by using the ink composition as described above.

Additionally, when two electrodes produced by using the ink composition have several different distances between the electrodes, the average length of the metal nanowires is determined based on the shortest distance between the two electrodes.

Regardless of whether the electrodes have a fine pattern with the distance between the electrodes being 20 μm or so or have a fine pattern with the distance between the electrode being less than 20 μm, preferably 60% or less of the total number of the metal nanowires contained in the ink composition according to the present disclosure are those having lengths greater than 0.5 times the distance between the electrodes, in order to further ensure the prevention of short circuit between the electrodes.

In order also to further improve conductivity of the transparent conductive film, preferably 50% or less, more preferably 30% or less, of the total number of the metal nanowires are those having lengths of 5 μm or less.

From the viewpoint of visibility, the metal nanowires also have an aspect ratio (average length/average diameter) preferably in the range from 10 to 50000.

The average length and length distribution of the metal nanowires may be evaluated from electron micrographs.

### (1-1-2) Colored Compounds

Preferably, the ink composition according to the present disclosure also contains colored compounds that may adsorb to the metal nanowires, with the colored compounds being adsorbed or unadsorbed. The colored compounds may be preadsorbed as an aggregate. Such a colored compound has absorption in the visible light region. The colored compound is represented by the general formula [R-X] wherein R represents a chromophoric group having absorption in the visible light region and X represents a functional group that may be adsorbed to the metal nanowires.

In the general formula, the chromophoric group [R] includes at least one of an unsaturated alkyl group, an aromatic ring, and a heterocyclic ring. Examples of the chromophoric group [R] include a nitroso group, a nitro group, an azo group, a methine group, an amino group, a ketone group, a thiazolyl group, a naphthoquinone group, and metal ion. Preferable examples of the chromophoric group [R] include a stilbene derivative, an indophenol derivative, a diphenylmethane derivative, an anthraquinone derivative, a triarylmethane derivative, a diazine derivative, an indigoid derivative, a xanthene derivative, an oxazine derivative, a phthalocyanine derivative, an acridine derivative, a thiazine derivate, and a sulfur atom-containing compound. From the viewpoint of improving transparency of the transparent conductive film formed by using the ink composition, the chromophoric group [R] may preferably be a Cr complex, a Cu complex, a Co complex, a Ni complex, a Fe complex, or an azo group- or indoline group-containing compound.

On the other hand, the functional group [X] of the colored compound may include an atom, such as nitrogen (N), sulfur (S), and oxygen (O), that may coordinate to the metal(s) constituting the metal nanowires. Preferable examples of the functional group [X] include a sulfo group (including sulfonate), a sulfonyl group, a sulfonamide group, a carboxylic acid group (including a carboxylate salt), an amino group, an amide group, a phosphate group (including a phosphate and a phosphate ester), a phosphino group, a silanol group, an epoxy group, an isocyanate group, a cyano group, a vinyl group, a thiol group, a sulfide group, and a carbinol group. At least one functional group [X] may be present in the colored compound. From the viewpoint of preventing a decrease in conductivity due to adsorption of the colored compound, the functional group [X] may preferably be a carboxylic acid group, a phosphate group, an amino group, a thiol group, or the like and may more preferably be a carboxylic acid group or a thiol group.

As the colored compound having the functional group [X], a self-assembled material may also be used. The functional group [X] may also be a component of the chromophoric group [R].

Examples of the colored compound described above include acidic and direct dyes.

Preferable examples of a dye having a sulfo group include Kayakalan BordeauxBL, Kayakalan Brown GL, Kayakalan Gray BL167, Kayakalan Yellow GL143, KayakalanBlack 2RL, Kayakalan Black BGL, Kayakalan Orange RL, Kayams Cupro Green G, Kayams Supra Blue MRG, Kayams Supra Scarlet BNL200 manufactured by Nippon Kayaku Co., Ltd., and Lanyl Olive BG manufactured by Taoka Chemical Company, Limited. Other examples include Kayalon Polyester Blue 2R-SF, Kayalon Microester Red AQ-LE, Kayalon Polyester Black ECX300, and Kayalon Microester Blue AQ-LE manufactured by Nippon Kayaku Co., Ltd.

Furthermore, preferable examples of a dye having a carboxyl group include a pigment for dye-sensitized solar cells. Examples of such a pigment include: N3, N621, N712, N719, N749, N773, N790, N820, N823, N845, N886, N945, K9, K19, K23, K27, K29, K51, K60, K66, K69, K73, K77, Z235, Z316, Z907, Z907Na, Z910, Z991, CYC-B1, and HRS-1, which are each a Ru complex; and Anthocyanine, WMC234, WMC236, WMC239, WMC273, PPDCA, PTCA, BBAPDC, NKX-2311, NKX-2510, NKX-2553, NKX-2554, NKX-2569, NKX-2586, NKX-2587, NKX-2677, NKX-2697, NKX-2753, NKX-2883, NK-5958, NK-2684, Eosin Y, Mercurochrome, MK-2, D77, D102, D120, D131, D149, D150, D190, D205, D358, JK-1, JK-2, JK-5, ZnTPP, H2TC1PP, H2TC4PP, a phthalocyanine dye (zinc phtalocyanine-2,9,16,23-tetra-carboxylic acid), 2-[2′-(zinc9′,16′,23′-tri-tert-butyl-29H,31H-phthalocyanyl)] succinic acid, a polythiohene dye (TT-1), a pendant type polymer, a cyanine dye (P3TTA, C1-D, SQ-3, B1), as an organic pigment. Sellers of these examples are, for example, Nippon Kayaku Co., Ltd., Taoka Chemical Co., Ltd., Hayashibara Biochemical Laboratories, Incorporated, Mitsubishi Paper Mills, Ltd., and Soken Chemical & Engineering Co., Ltd.

Preferable examples of a thiol group-containing colored compound may be appropriately selected in accordance with purposes and may be, but not limited to, (i) a reactant between a acidic group-containing dye and a basic group-containing thiol molecule, (ii) a reactant between a basic group-containing dye and an acidic group-containing thiol molecule, and (iii) a reactant between a reactive group-containing dye and a hydroxyl group-containing thiol molecule. These examples may be used alone or in a combination of two or more.

Preferably, the colored compounds are dissolvable to the solvent contained in the ink composition. Furthermore, when being contained in the ink composition according to the present disclosure, the colored compounds may be partially or entirely adsorbed to the metal nanowires. The colored compounds may also be adsorbed as an aggregate to the metal nanowires.

Incidentally, treating the surfaces of metal nanowires with colored compounds may improve durability of the metal nanowires.

### (1-1-3) Photosensitive Material

A photosensitive material refers to a material that undergoes chemical reaction when exposed to radiation of light, electron beams or radiant rays and as a result, changes its solubility in the solvent. Such a photosensitive material includes a positive type (in which a portion thereof exposed to the radiation is dissolved) and a negative type (in which a portion thereof exposed to the radiation remains undissolved), both of which may be used. In the case of the positive type, a process of curing an unexposed portion remaining after a development process is required, whereas, in the case of the negative type, this curing process may be omitted. Accordingly, from the viewpoint of curtailing the process, the negative type is preferably used.

### <Positive-Type Photosensitive Material>

As the positive-type photosensitive material, a known photoresist material of positive type may be used. Examples include a composition containing a polymer (such as a novolak resin, an acrylic copolymer resin, and hydroxylated polyamide) and a naphthoquinone diazide compound.

### <Negative-Type Photosensitive Material>

As the negative-type photosensitive material, for example, (i) a polymer in which a photosensitive group has been introduced in at least one of a main chain and a side chain thereof, (ii) a composition containing a binder resin (polymer) and a crosslinker, and (iii) a composition containing at least one of (meth)acrylic monomer and (meth)acrylic oligomer and also containing a photopolymerization initiator may be used.

The negative-type photosensitive material may undergo any chemical reactions, and examples of the reactions include a photodimerization reaction of stilbene, maleimide, or the like via a photopolymerization initiator, and a cross-linking reaction of an azide group, a diazirine group, or the like as a result of photodegradation. In the above examples, the photodegradation reaction of an azide group, a diazirine group, or the like may be preferably used from the viewpoint of curing reactivity mainly owing to the unsusceptibility to reaction inhibition by oxygen and the excellent solvent resistance, hardness, and scuff resistance of the cured film.

(i) Polymer in which Photosensitive Group has been Introduced in at Least One of Main Chain and Side Chain Thereof

Examples of the photosensitive group include a functional group having a nitrogen atom, a functional group having a sulfur atom, a functional group having a bromine atom, a functional group having a chlorine atom, and a functional group not having any of these atoms. Preferable examples include a functional group having an azide group, a functional group having a diazirine group, a functional group having a stilbene group, a functional group having a chalcone group, a functional group having a diazonium base, a functional group having a cinnamic acid group, and a functional group having an acrylic acid group. In the above examples, an azide group and a diazirine group may be preferably used.

Preferably, the polymer in which a photosensitive group has been introduced in at least one of the main chain and the side chain thereof does not inhibit dispersibility of the metal nanowires and is water-soluble. A water-soluble polymer as used herein refers to a compound having ionic or polar side chains in amounts necessary and sufficient for a main chain within the molecule so that the compound may be dissolved in water. The water-soluble polymer in which a photosensitive group has been introduced in at least one of the main chain and the side chain thereof preferably has a solubility in water at 25° C. of 1 (g) or more (per water of 100 g).

Examples of the polymer in which a photosensitive group has not yet been introduced in at least one of the main chain and the side chain thereof include polyvinyl alcohol, polyvinyl butyral, polyvinyl pyrrolidone, polyvinyl acetamide, polyvinyl formamide, polyvinyl oxazolidone, polyvinyl succinimide, polyacrylamide, polymethacrylamide, polyethyleneimine, a polyvinyl acetate-based polymer (e.g., a saponified product of polyvinyl acetate), a polyoxyalkylene-based polymer (e.g., polyethyleneglycol and polypropylene glycol), a cellulose-based polymer (e.g., methyl cellulose, viscose, hydroxyethyl cellulose, hydroxyethylmethyl cellulose, carboxymethyl cellulose, and hydroxypropyl methylcellulose), a natural polymer (e.g., gelatin, casein, collagen, arabic gum, xanthan gum, tragacanth gum, guar gum, pullulan, pectin, sodium alginate, hyaluronic acid, chitosan, chitin derivative, carageenan, starchs such as carboxymethyl starch and aldehyde starch, dextrin, and cyclo-dextrin), and a copolymer composed of monomers of these polymers. Two or more of these example (co)polymers may also be used together.

Preferably, the polymer in which a photosensitive group has been introduced in at least one of the main chain and the side chain thereof is of, for example, the following general formula (I). This structure allows production of ink without inhibiting dispersibility of the metal nanowires. The above structure also allows formation of a uniform film on a substrate and production of a transparent conductive film and transparent electrodes with a predetermined pattern at a practical wavelength in the range from 300 to 500 nm.

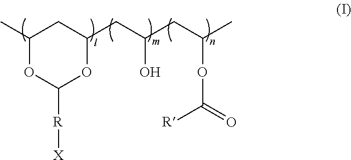

In the general formula (I), X represents one or more photosensitive groups containing at least one of the azide group and the diazirine grouper represents one of a chain or cyclic alkylene group and a derivative thereof and may contain, in at least one of a main chain and a side chain thereof, one or more of an unsaturated bond, an ether bond, a carbonyl bond, an ester bond, an amide bond, an urethane bond, a sulfide bond, an aromatic ring, a heterocyclic ring, an amino group, and a quaternary ammonium base. R′ represents one of a chain or cyclic alkyl group and a derivative thereof and may contain, in at least one of a main chain and a side chain thereof, one or more of an unsaturated bond, an ether bond, a carbonyl bond, an ester bond, an amide bond, an urethane bond, a sulfide bond, an aromatic ring, a heterocyclic ring, an amino group, and a quaternary ammonium base. Furthermore, 1 is 1 or more, m is 1 or more, and n is 0 or more.

### (ii) Composition Containing Binder Resin (Polymer) and Crosslinker

Preferably, the binder resin (polymer) does not inhibit dispersibility of the metal nanowires and is a water-soluble polymer. A water-soluble polymer as used herein refers to a polymer having ionic or polar side chains in amounts necessary and sufficient for a main chain within the molecule so that the polymer may be dissolved in water. The water-soluble polymer used herein preferably has a solubility in water at 25° C. of 1 (g) or more (per water of 100 g). Examples of the water-soluble polymer include polyvinyl alcohol, polyvinyl butyral, polyvinyl pyrrolidone, polyvinyl acetamide, polyvinyl formamide, polyvinyl oxazolidone, polyvinyl succinimide, polyacrylamide, polymethacrylamide, polyethyleneimine, a polyvinyl acetate-based polymer (e.g., a saponified product of polyvinyl acetate), a polyoxyalkylene-based polymer (e.g., polyethyleneglycol and polypropylene glycol), a cellulose-based polymer (e.g., methyl cellulose, viscose, hydroxyethyl cellulose, hydroxyethylmethyl cellulose, carboxymethyl cellulose, and hydroxypropyl methylcellulose), a natural polymer (e.g., gelatin, casein, collagen, arabic gum, xanthan gum, tragacanth gum, guar gum, pullulan, pectin, sodium alginate, hyaluronic acid, chitosan, chitin derivative, carageenan, starchs such as carboxymethyl starch and aldehyde starch, dextrin, and cyclo-dextrin), and a copolymer composed of monomers of these polymers. Two or more of these example (co)polymers may also be used together.

Preferably, the crosslinker does not inhibit dispersibility of the metal nanowires and is water-soluble. The water-soluble crosslinker means that the crosslinker is capable of providing an aqueous solution having a concentration of 0.1 mM or more. Examples of the crosslinker include a bisazide compound, an aromatic bisazide compound, a multifunctional azide compound, an aromatic multifunctional azide compound, a diazirine compound, an aromatic diazirine compound, hexamethoxymethylmelamine, tetramethoxy glycouril. Two or more of these example crosslinkers may also be used together. In these examples, a bisazide compound, an aromatic bisazide compound, a multifunctional azide compound, an aromatic multifunctional azide compound, a diazirine compound, and an aromatic diazirine compound may be preferably used.

(iii) Composition Containing at Least One of (Meth)Acrylic Monomer and (Meth)Acrylic Oligomer and Also Containing Photopolymerization Initiator

The composition containing at least one of (meth)acrylic monomer and (meth)acrylic oligomer and also containing a photopolymerization initiator is another option that may be used as the photosensitive material. Preferably, these do not inhibit dispersibility of the metal nanowires and are water-soluble. More preferably, these have a solubility in water at 25° C. of 1 (g) or more (per water of 100 g).

Preferable examples of the negative-type photosensitive material include polyvinyl alcohol containing a photosensitive group azide, and an aqueous UV polymer (e.g., O-106, O-391, or the like which are manufactured by Chukyo Yushi Co., Ltd.).

### (1-1-4) Solvent

As the solvent, a single solvent or a mixed solvent that allows the metal nanowires to be dispersed therein and that also allows the colored compounds to be dispersed or dissolved therein may be used. Preferable examples of the solvent include water, alcohol (e.g., methanol, ethanol, n-propanol, i-propanol, n-butanol, i-butanol, sec-butanol, and tert-butanol), anon (e.g., cyclohexanone and cyclopentanone), amide (e.g., N,N-dimethylformamide: DMF), and sulfide (e.g., dimethyl sulfoxide: DMSO). These examples may be used alone or in combination.

Furthermore, in order to prevent uneven drying, cracks, and decoloration of the film formed by using the ink composition, a high boiling point solvent may be added to the ink composition as the solvent. Addition of the high boiling point allows control over the rate at which the solvent evaporates from the ink composition. Examples of the high boiling point solvent include butyl cellosolve, diacetone alcohol, butyl triglycol, propylene glycol monomethyl ether, propylene glycol monoethyl ether, ethylene glycol monoethyl ether, ethylene glycol monopropyl ether, ethylene glycol monoisopropyl ether, diethylene glycol monobutyl ether, diethylene glycol monoethyl ether, diethylene glycol monomethyl ether, diethylene glycol diethyl ether, dipropylene glycol monomethyl ether, tripropylene glycol monomethyl ether, propylene glycol monobutyl ether, propylene glycol isopropyl ether, dipropylene glycol isopropyl ether, tripropylene glycol isopropyl ether, and methyl glycol. These example high boiling point solvents may be used alone or in combination or two or more.

### (1-1-5) Other Additives

In addition to the components described so far, the ink composition according to the present disclosure may also contain, as additives, a light stabilizer, a ultraviolet light absorber, a light absorbing material, an antistatic agent, a lubricant, a leveling agent, an antifoaming agent, a flame retarder, an infrared light absorber, a surfactant, a viscosity modifier, a dispersing agent, a curing acceleration catalyst, a plasticizer, an antioxidant, and an anti-sulfurization agent, as needed.

### (1-2) Method for Producing Ink Composition

The ink composition according to the present disclosure may be produced by mixing the aforementioned components and dispersing the metal nanowires.

At this time, a blending ratio of the metal nanowires and a photosensitive resin is preferably in the range from 0.05 to 50 in weight ratio. The blending ratio of less than 0.05 might cause difficulty in forming a network of the metal nanowires contacting each other in the film, often resulting in an increase in sheet resistance of the transparent conductive film formed by using the ink composition. On the other hand, the blending ratio of greater than 50 might hinder the formation of a film of the ink composition per se and produce a film that tends to be damaged during the process and handling.

Furthermore, a blending ratio of the colored compounds with respect to the metal nanowires is preferably in the range from 0.001 to 10 weight %. Blending the colored compounds will provide an advantageous effect of reducing a reflectance lightness (L) value (i.e., an L* value obtained from measurement of a reflectance and spectral transmittance according to the L*a*b* color expression system). This reflectance L value reduction effect is more effective at a higher blending ratio of the colored compounds. However, excessive loading of the colored compounds will tend to cause aggregation of the metal nanowires in the dispersion liquid, and this leads to decreases in sheet resistance and total light transmittance of the resulting transparent conductive film. Accordingly, the blending ratio of the colored compounds with respect to the metal nanowires is preferably in the range from 0.001 to 10 weight % as described above.

With this constitution, the content of colored compounds that are unadsorbed to the metal nanowires in the transparent conductive film according to the present disclosure formed by using the ink composition according to the present disclosure is regulated to be in the range preferably from 0.05 to 9.9 weight %, more preferably from 0.1 to 9 weight %. As a result, transparency of the transparent conductive film is improved. The content of colored compounds in the transparent conductive film that are unadsorbed to the metal nanowires may be determined by appropriately selecting a solvent that is capable of dissolving the transparent conductive film without adversely affecting the state of adsorption of the colored compounds to the metal(s), by determining absorbance spectrum of the solution thereof, and by measuring the concentration of the colored compounds in the solution.

The ink composition according to the present disclosure in which at least part of the colored compounds are adsorbed to the metal nanowires may be manufactured by the following processes.

(Process A) Preparation of Colored Compound

As such a colored compound, a commercially available dye may be prepared as a compound of the aforementioned general formula [R-X]. Alternatively, the colored compound may be synthesized from a compound having the chromophoric group R and a compound having the functional group X that may be easily adsorbed to the metal nanowires.

(Process B) Adsorption of Colored Compounds to Metal Nanowires

From the colored compounds and a solvent, a solution of the colored compounds is prepared. Similarly, from the metal nanowires and a solvent, a dispersion liquid of the metal nanowires is prepared. The prepared solution and dispersion liquid are mixed and, as needed, are left still and subjected to appropriate processes such as stirring, heating, and ultrasonic radiation, thereby causing the colored compounds to adsorb to the surfaces of the metal nanowires. The process of causing the colored compounds to adsorb to the metal nanowires may be repeated several times. When the ink composition contains an excessively large amount of colored compounds that remain unadsorbed, transparency of the transparent conductive film formed by using the ink composition is deteriorated. For this reason, in case of difficulty in achieving a desired transparency of the transparent conductive film due to the large amount of colored compounds that are unadsorbed, such as when a total light transmittance of the transparent conductive film does not reach 80%, these unadsorbed color compounds may be separated and removed by adding a poor solvent as needed.

(Process C) Dispersion Process in Photosensitive Resin

The metal nanowires to which the colored compounds have been adsorbed by the process B, a photosensitive resin, and a solvent, and as needed, other additives are mixed and dispersed. The dispersion process may be accomplished by a magnetic stirrer, shaking by hand, stirring in a jar mill, a mechanical stirrer, ultrasonic radiation, shear force dispersion, or the like.

When the ink composition is left still after the dispersion process, the metal nanowires settle down in some cases. In these cases, the metal nanowires may be dispersed by conducting the dispersion process again.

### (2) Transparent Conductive Film and Patterning Thereof

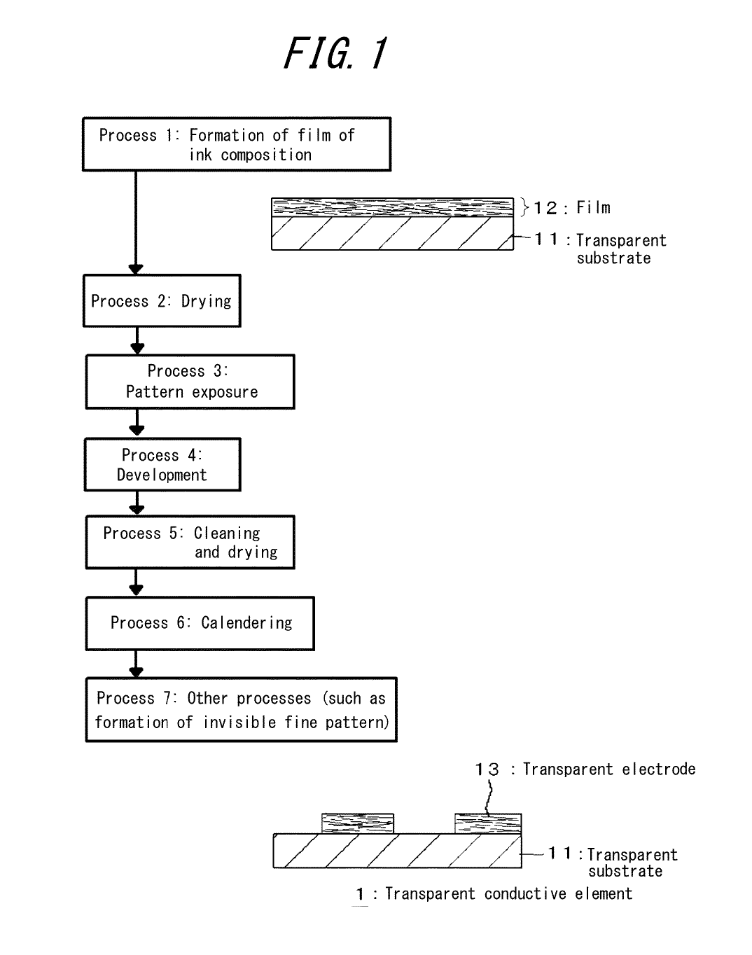

The transparent conductive film according to the present disclosure may be formed by drying and curing a film of the aforementioned ink composition according to the present disclosure. Furthermore, the following processes illustrated in FIG. 1 may be used to produce transparent electrodes having a predetermined pattern by using the transparent conductive film according to the present disclosure.

(Process 1) Formation of Film of Ink Composition

To begin with, a film 12 of the ink composition is formed on a surface of a transparent substrate 11. As the transparent substrate 11, any substrate that is made of a transparent inorganic material or a plastic and that has a film, plate, or block shape may be used. Examples of the inorganic material herein include quartz, sapphire, and glass. Examples of the plastic include triacetyl cellulose (TAC), thermoplastic elastomer polyester (TPEE), polyethylene terephthalate (PET), polyethylene naphthalate (PEN), polyimide (PI), polyamide (PA), aramid, polyethylene (PE), polyacrylate, polyether sulfone, polysulfone, polypropylene (PP), polystyrene, diacetyl cellulose, polyvinyl chloride, an acrylic resin, a methacrylate resin (PMMA), polycarbonate (PC), an epoxy resin, an urea resin, an urethane resin, a melamine resin, a phenolic resin, an acrylonitrile-butadiene-styrene copolymer, a cycloolefin polymer (COP), a cycloolefin copolymer (COC), a PC/PMMA laminate, PMMA coated with rubber. The base material may include an inorganic filler and a high polymer material. Decorations such as a design and a pattern may be printed or vapor-deposited onto the transparent substrate 11. Furthermore, the transparent substrate 11 may be provided, for example, with a circuit such as a TFT device or with a color filter.

When the transparent substrate 11 is to be used as a substrate for transparent electrodes in an image display device, preferably, the thickness of the transparent substrate 11 is typically in the range from 5 μm to 5 mm.

Various methods, such as a coating method, a spraying method, and a printing method, may be employed for forming the film 12 of the ink composition on the surface of the transparent substrate 11. Examples of the coating method include a micro-gravure coating method, a wire bar coating method, a direct gravure coating method, a die coating method, a dipping method, a spray coating method, a reverse roll coating method, a curtain coating method, a comma coating method, a knife coating method, and a spin coating method. Examples of the printing method include anastatic, offset, gravure, intaglio, rubber plate, screen, and ink jet printings.

(Process 2) Drying of Film

The solvent contained in the film 12 of the ink composition formed in Process 1 is dried for removal. The drying process may be accomplished by natural drying or by heating. After being dried, the film may be compressed with a calender as needed in order to reduce the sheet resistance of the transparent conductive film.

(Process 3) Pattern Exposure

Pattern exposure may be implemented by using a mask or a direct-write laser. As a mask exposure method, any of a contact exposure method (e.g., hard contact exposure and soft contact exposure) and a non-contact exposure method (e.g., proximity exposure, one-shot projection exposure, lens projection exposure, and mirror projection exposure) may be used. For example, a high pressure mercury lamp, an ultra-high pressure mercury lamp, an electrodeless lamp valve, and an excimer laser (e.g., KrF, ArF, and F₂) may be used as a light source. The integrated light quantity may be appropriately selected within the range from 1 mJ/cm² to 5000 mJ/cm² in accordance with a photosensitive resin material used. The cumulative light quantity of less than 1 mJ/cm² might result in an insufficient chemical reaction of the photosensitive resin in an exposed portion, often leading to a failure of development of the pattern. On the other hand, the cumulative light quantity of greater than 5000 mJ/cm² might provoke a chemical reaction of the photosensitive resin even in a light shield portion or a non-exposed portion due to propagation, reflection, or the like of light. This deteriorates a resolution of the pattern.

(Process 4) Development

As a developer, any of a solvent contained in the ink composition, water, an alkaline aqueous solution (e.g., an aqueous solution of sodium carbonate, an aqueous solution of hydrogen sodium carbonate, an aqueous solution of tetramethylammonium hydroxide, or the like), an acidic aqueous solution (e.g., an aqueous solution of hydrochloric acid, an aqueous solution of phosphoric acid, an aqueous solution of acetic acid, an aqueous solution of citric acid, or the like) may be used. Examples of a method of development include a method of immersing the transparent electrodes, whether being kept in a still or a stirred condition, in the developer, and a method of spraying a shower of the developer to the transparent electrodes. Consequently, the exposed portion (in the case of the positive-type photosensitive resin) or the non-exposed portion (in the case of the negative-type photosensitive resin) of the transparent conductive film formed in Process 3 is dissolved out, and the transparent electrodes are patterned.

(Process 5) Cleaning and Drying

After the development in Process 4, the transparent electrodes are immersed in, or sprayed with a shower of, water or alcohol (e.g., methanol, ethanol, n-propanol, i-propanol, n-butanol, i-butanol, sec-butanol, tert-butanol, or the like) and dried, for example, by natural drying, by heating, or by air blow.

(Process 6) Calendering

Subsequently, in order to improve conductivity of the transparent electrodes, compression treatment, such as roll pressing or flat plate pressing, is preferably performed. Additionally, the calendering may also be conducted prior to the pattern exposure in Process 3.

(Process 7) Other Processes

As needed, the transparent electrodes may also be formed with an invisible fine pattern. An invisible fine pattern refers to a technique of inhibiting visibility of an electrode pattern by forming a plurality of holes on the surfaces of transparent electrodes and also forming a plurality of protrusions on the surface of an insulating portion of a substrate in which no transparent electrode is present. The plurality of holes and protrusions may be formed by etching or printing methods in accordance with the descriptions in Japanese Patent No. 4862969. Forming the invisible fine pattern further improves invisibility of the electrode pattern.

Furthermore, an overcoat layer that protects the transparent electrodes may be formed on an electrode pattern of the transparent conductive film. The overcoat layer essentially has light transmittance to the visible light and may be composed of, for example, a polyacrylic-based resin, a polyamide-based resin, a polyester-based resin, a cellulose-based resin, or a hydrolysate or a dehydrated condensate of metal alkoxide.

When the overcoat layer is formed, it is preferable that at least part of the metal nanowires are exposed at the surface of the overcoat layer. The reason is that doing so will facilitate securing an electric connection with other conductive portions.

The overcoat layer may be provided with at least one function selected from a hard coating function, an antiglare function, an antireflective function, an anti Newton-ring function, an anti-blocking function, or the like.

By thus pattern exposing a photosensitive resin contained in the ink composition, a transparent conductive element 1, including electrodes 13 having a predetermined pattern and produced by using the transparent conductive film, is formed in fewer processes than a conventional pattern etching method. In detail, when a photosensitive resin is not used as a binder resin for dispersing the metal nanowires, the electrodes having a predetermined pattern and produced by using the transparent conductive film cannot be achieved until the following processes are performed. That is to say, after forming the transparent conductive film by using the ink composition, a photoresist film is formed on the transparent conductive film, the photoresist is patterned by pattern exposing and developing the formed photoresist film, the transparent conductive film is etched by using the patterned photoresist as a mask, and thus, the electrodes having the predetermined pattern are produced. Accordingly, the ink composition according to the present disclosure eliminates the needs for the formation of a photoresist on the transparent conductive film, the pattern exposure, and the development.

The transparent conductive film formed by using the ink composition according to the present disclosure is not limited to the aforementioned transparent conductive film resulting from the pattern exposure and includes the one that has been solidly exposed.

In an embodiment, the ink composition according to the present disclosure does not contain a colored compound. In this case, by using the ink composition, a transparent conductive film containing metal nanowires to which colored compounds are adsorbed may be formed, for example, by the following method. That is to say, firstly, a transparent conductive film is formed by using the ink composition which does not contain a colored compound, and then, prior to or after being patterned, the formed transparent conductive film is immersed in a liquid in which colored compounds are dissolved or dispersed, thereby causing the colored compounds to adsorb to the metal nanowires contained in the transparent conductive film.

### (3) Image Display Device

The electrodes of the transparent conductive film formed by using the ink composition according to the present disclosure is useful, for example, as transparent electrodes used in a liquid crystal display or as transparent electrodes used in a touch panel disposed on an image display surface side of an image display panel made of a liquid crystal display or the like.

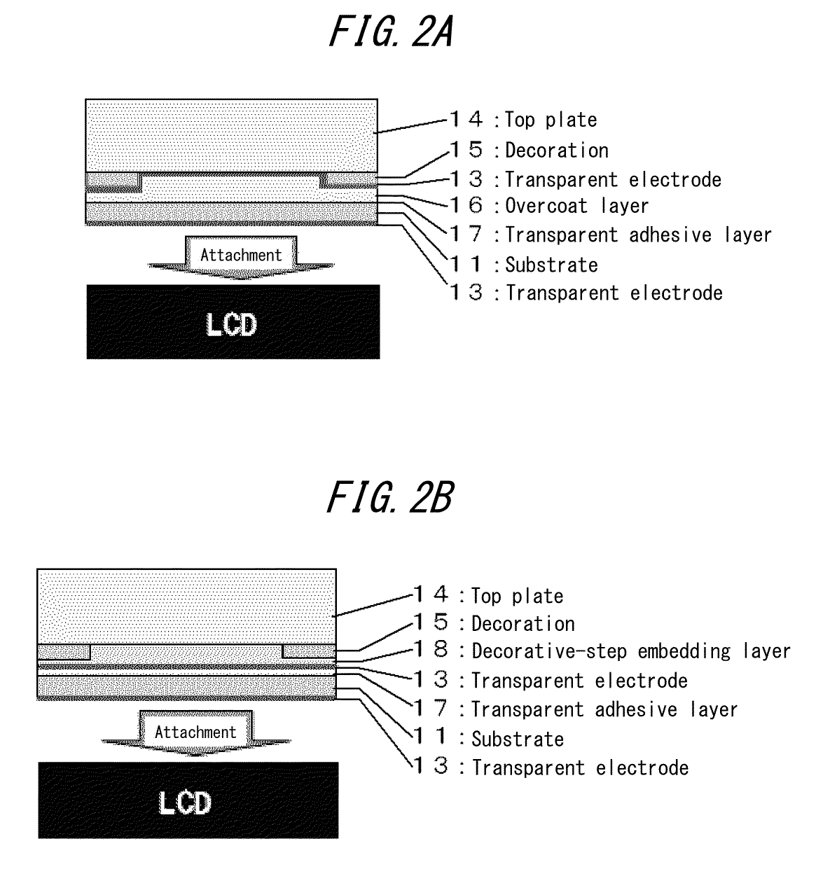

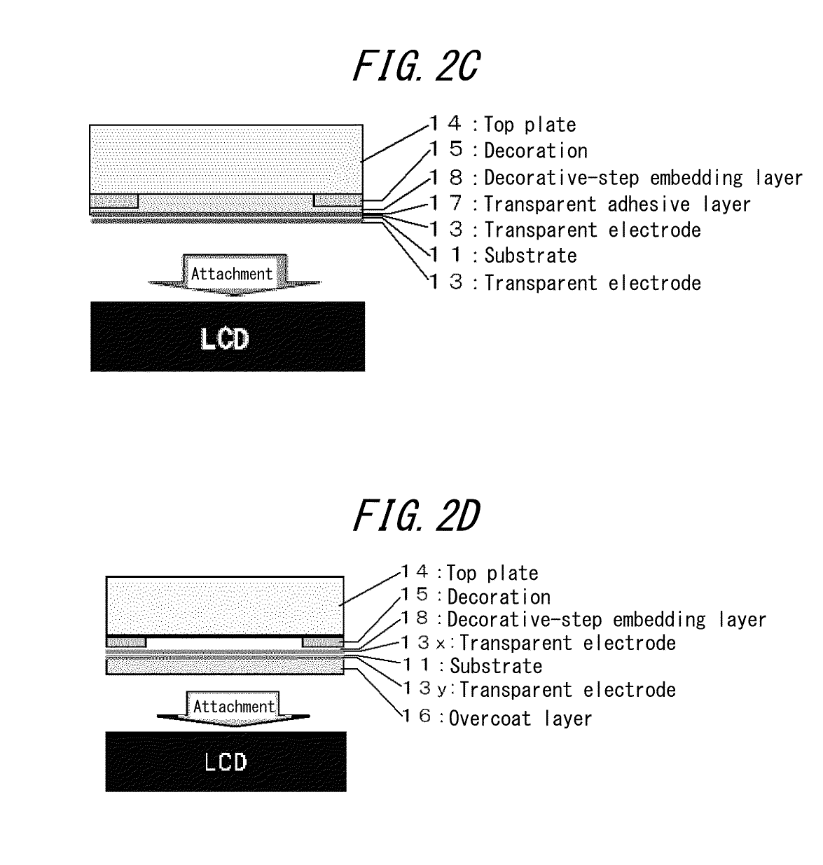

FIGS. 2A, 2B, 2C, and 2D are schematic views illustrating exemplary configurations of touch panels using the transparent conductive films according to the present disclosure. In each exemplary configuration, the touch panel is adhered to a liquid crystal display (LCD) by a transparent adhesive or the like. In the figures, details such as extraction electrodes are omitted.

The touch panel illustrated in FIG. 2A includes a top plate 14 on which decorations 15 and transparent electrodes 13 are directly formed. The top plate 14 is located as the outermost surface of the touch panel, thus serving as an operation surface. The top plate 14 may be made of glass, such as quartz glass, sapphire glass, and soda glass, or of plastic, such as polycarbonate, PMMA, PET, cycloolefin copolymer (COC), and cycloolefin polymer (COP), and may be in the form of a laminate body of one or two or more of these materials. The top plate 14 may be provided with a hard coating (HC) layer, an antireflective (AR) function, an antiglare (AG) layer, an antiglare and low reflection (AGLR) layer, a black floating prevention layer, a moss eye-like structure, or the like. The transparent electrodes 13 may be patterned in a linear pattern, a diamond pattern, or the like. The overcoat layer 16 covers the transparent electrodes 13 to protect the transparent electrodes 13.

The touch panel illustrated in FIG. 2B includes a decorative-step embedding layer 18. In this touch panel, the decorative-step embedding layer 18 is disposed to eliminate a step caused by the decorations 15, thereby flattening the forming surface of the transparent conductive film. The decorative-step embedding layer 18 may be made of a radiation setting resin (e.g., an acrylic resin or the like) or a thermosetting resin (e.g., an epoxy resin or the like).

The touch panel illustrated in FIG. 2C includes the transparent electrodes 13 formed on both sides of the transparent substrate 11.

The touch panel illustrated in FIG. 2D includes transparent electrodes using jumper wires that are formed on the decorative-step embedding layer 18. The transparent electrodes using jumper wires have one transparent electrode pattern 13x extending in a direction x and another transparent electrode pattern 13y extending in a direction y on the same surface of the transparent substrate 11. Furthermore, at intersections between the transparent electrode pattern 13x and the transparent electrode pattern 13y, connecting portions in which the one transparent electrode pattern 13x straddles the other transparent electrode pattern 13y are formed. As the overcoat layer 16 of this touch panel, an antireflective (AR) layer or the like may be formed. Alternatively, the overcoat layer 16 may be provided with a moss eye-like structure.

### EXAMPLES

In the following, the embodiments are described in detail with reference to Examples.

### Example 1

Firstly, silver nanowires were prepared as metal nanowires. The silver nanowires were prepared with reference to the publication ACS Nano, 2010, VOL. 4, NO. 5, pp. 2955-2963. The silver nanowires had an average diameter of 30 nm and an average length of 10 μm evaluated from an electron micrograph as described below.

Subsequently, the prepared silver nanowires (Ag 1) and the following materials were placed into a water/ethanol mixed solvent, and thus, a dispersion liquid in which the silver nanowires were dispersed in the solvent was prepared.
Silver nanowires (Ag 1): 0.11 weight %
BIOSURFINE-AWP of the general formula (II) below manufactured by Tokyo Gosei Co., Ltd.: 0.272 weight %
Colored Compound (a compound obtained by reacting Lanyl Black BG E/C manufactured by Okamoto Dyestuff Co., Ltd. with 2-aminoethanethiol manufactured by Tokyo Chemical Industry Co., Ltd. in advance): 0.03 weight %
Water: 89.588 weight %
Ethanol: 10 weight %

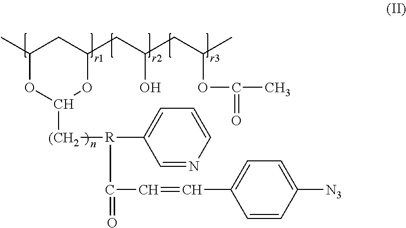

(r1=1 to 1000, r2=40 to 4995, r3=0 to 4000, ₙ=1, 2, or 3, R represents alkylene group having carbonyl and amine)

The prepared dispersion liquid was applied onto a transparent substrate with a No. 8 coil bar to form a dispersion film. The coating amount of the silver nanowires was approximately 0.02 g/m². As the transparent substrate, PET (Lumirror® U34 manufactured by Toray Industries, Inc.) having a thickness of 100 μm was used. Subsequently, the transparent substrate was heated at 80° C. for 3 minutes in the atmosphere, and the solvent in the dispersion film was dried for removal.

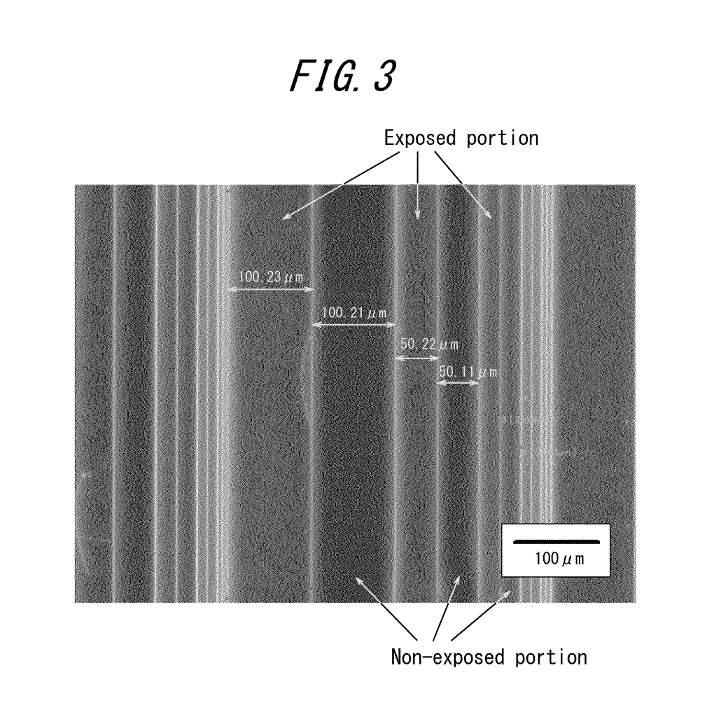

The film was brought into a soft contact with a photomask illustrated in FIG. 3 and irradiated with ultraviolet rays at an integrated light quantity of 10 mJ by using an alignment exposure device manufactured by Toshiba Lighting & Technology Corporation to cure an exposed portion. Subsequently, 100 mL of a 20% by weight acetic acid aqueous solution was sprayed in the form of a shower onto the film to remove a non-exposed portion, followed by development. After that, calendering (at a nip width of 1 mm, a load of 4 kN, and a rate of 1 m/min) was conducted, and thus, transparent electrodes were produced.

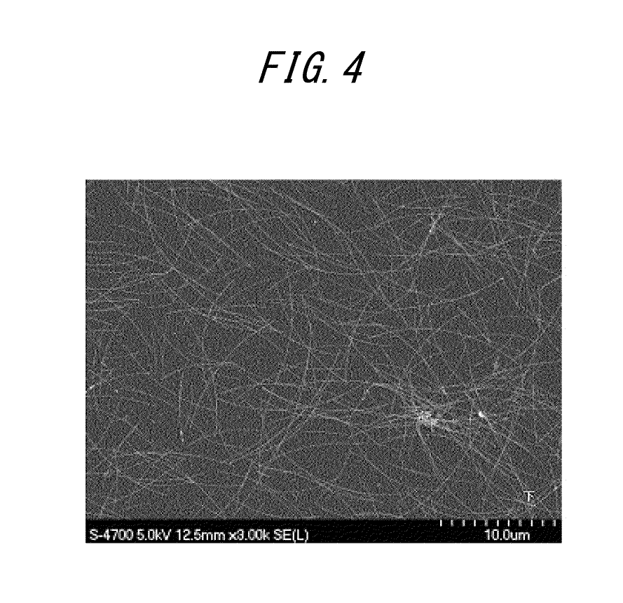

The produced transparent electrodes were imaged at a magnification of from 2000 to 3000 times by a Field Emission Scanning Electron Microscope S-4700 manufactured by Hitachi, Lading the obtained electron micrograph, 50 to 200 or more silver nanowires were observed, and the shapes of these silver nanowires were also evaluated. The obtained image is illustrated in FIG. 4. The length of each nanowire was determined by calculating a projected diameter and a projected area of the nanowire from the electron micrograph by using an image analysis device and by making another calculation based on the following formula while assuming that the nanowire had a cylindrical shape.

Length=Projected area/Projected diameter

Table 1 shows distribution of the lengths of the silver nanowires (percentages of how many silver nanowires fall into predetermined length ranges) obtained from the above evaluation.

### Examples 2 and 3

For Examples 2 and 3, transparent electrodes were produced in the same way as Example 1 except for that DEN manufactured by Shinko Corporation (in Example 2) and LA1920 manufactured by Taoka Chemical Co., Ltd, (in Example 3), instead of Lanyl Black BG E/C manufactured by Okamoto Dyestuff Co., Ltd., were used as colored compounds.

### Examples 4 and 5

For Examples 4 and 5, transparent electrodes were produced in the same way as Example 1 except for that the integrated light quantities during irradiation were changed to 1 mJ (in Example 4) and 5000 mJ (in Example 5).

### Example 6

A dispersion liquid was prepared by dispersing the following materials including the silver nanowires (Ag1) used in Example 1.
Silver nanowires (Ag1): 0.11 weight %
Urethane acrylate oligomer (CN9006 manufactured by Sartomer Company, Inc.): 0.176 weight %
Pentaerythritol triacrylate (triester 37%)(A-TMM-3 manufactured by Shin-Nakamura Chemical Co., Ltd.): 0.088 weight %
Photopolymerization initiator (IRGACURE 184 manufactured by BASF Japan Ltd.): 0.008 weight %
Colored Compound (a compound obtained by reacting Lanyl Black BG E/C manufactured by Okamoto Dyestuff Co., Ltd. with 2-aminoethanethiol hydrochloride manufactured by Tokyo Chemical Industry Co., Ltd.): 0.03 weight %
IPA: 96.588 weight %
Diacetone alcohol (DAA): 3 weight % Subsequently, the same operations as those in Example 1 were conducted except for that the integrated light quantity was changed to 800 mJ, that nitrogen atmosphere was used as the exposure environment, and that the developer was changed from the 20% by weight acetic acid aqueous solution to IPA.

### Example 7

Silver nanowires (Ag 2) with an average diameter of 50 nm and an average length of 30 μm were prepared with reference to the publication ACS Nano, 2010, VOL. 4, NO. 5, pp. 2955-2963. Transparent electrodes were produced in the same way as Example 1 by using the prepared silver nanowires (Ag 2). An electron micrograph of the transparent electrodes was taken, and the lengths of the silver nanowires were evaluated. The result is shown in Table 1.

Table 1 shows distribution of the lengths of the silver nanowires.

### Example 8

Silver nanowires (Ag 3) with an average diameter of 50 nm and an average length of 50 μm were prepared with reference to the publication ACS Nano, 2010, VOL. 4, NO. 5, pp. 2955-2963. The same operations as those in Example 1 were conducted while the prepared silver nanowires (Ag 3) were used, and the lengths of the silver nanowires were evaluated. Table 1 shows distribution of the lengths of the silver nanowires.

### Example 9

Transparent electrodes were produced in the same way as Example 1 except for that the dispersion liquid was free from a colored compound.

### Comparative Example 1

Silver nanowires (Ag 4) with an average diameter of 60 nm and an average length of 100 μm were prepared with reference to the publication ACS Nano, 2010, VOL. 4, NO. 5, pp. 2955-2963. Transparent electrodes were produced in the same way as Example 1 except for that the prepared silver nanowires (Ag 4) were used, and the lengths of the silver nanowires were evaluated. Table 1 shows distribution of the lengths of the silver nanowires.

### Comparative Example 2

Transparent electrodes were produced in the same way as Example 1 except for that silver nanowires Agnws-L50 (manufacturer's values for the diameter of 50 nm and the length of 200 μm) manufactured by ACS Co., Ltd. were used instead of the silver nanowires (Ag1). Transparent electrodes were produced in the same way as Example 1 except for that the silver nanowires (Agnws-L50) were used, and the lengths of the silver nanowires were evaluated. Table 1 shows distribution of the lengths of the silver nanowires.

### Example 10

Silver nanowires (Ag 5) with an average diameter of 30 nm and an average length of 3 μm were prepared with reference to the publication ACS Nano, 2010, VOL. 4, NO. 5, pp. 2955-2963. Then, transparent electrodes were produced in the same way as Example 1 while the prepared silver nanowires (Ag 5) were used, and the lengths of the silver nanowires were evaluated. Table 1 shows distribution of the lengths of the silver nanowires.

Assessments

Each of the transparent electrodes of Examples 1 to 10 and Comparative Examples 1 and 2 was assessed for (A) a total light transmittance [%], (B) a haze value, (C) a sheet resistance [Ω/square], (D) an reflectance L value, (E) adhesion properties, (F) a resolution, and (G) invisibility as follows. Results of the assessments are shown in Table 2.

(A) Total Light Transmittance

A total light transmittance was assessed by a device (with a trade name: HM-150) manufactured by Murakami Color Research Laboratory Co., Ltd. in accordance with JIS K7361.

(B) Haze Value

A haze value was assessed by the device (with the trade name: HM-150) manufactured by Murakami Color Research Laboratory Co., Ltd. in accordance with JIS K7136.

(C) Assessment of Sheet Resistance

A sheet resistance was evaluated by a device (with a trade name MCP-T360) manufactured by Mitsubishi Chemical Analytic Co., Ltd.

(D) Reflectance L Value

A spectral reflectance was measured by Color i5 manufactured by X-Rite Company in accordance with JIS Z8722, and from the spectral data, an L* value in the L*a*b* color expression system was obtained.

(E) Adhesion Properties

Adhesion properties were assessed by a peel test using a cross-cut (1 mm interval×100 cuts) cellophane tape (CT24 manufactured by Nichiban Co., Ltd.) in accordance with JIS K5400.

(F) Resolution

A resolution was assessed by using VHX-1000 manufactured by Keyence Corporation in dark field at magnifications of from 100 to 1000 times according to the following assessment criteria.

Assessment Criteria for Resolution

AA: When, for all the randomly selected five spots in the film surface, tolerance ranges between line widths of 100, 50, 25, 12, 6, and 3 μm in the electrode pattern and photomask setting values are within ±10%.

A: The above tolerance ranges are within ±20%.

C: The above tolerance ranges exceed ±20%.

Note that, however, even when the tolerance ranges of the line widths in the electrode pattern are within ±10% or within ±20%, if the risk of short circuit due to contact between some silver nanowires lying outside the electrode pattern and other silver nanowires lying outside the electrode pattern is present, the corresponding resolution is assessed as C.

(G) Invisibility

The transparent electrodes of the above Examples and Comparative Examples were attached to 3.5 inch diagonal liquid crystal displays such that the silver nanowires of these transparent electrodes faced the display screens via adhesive sheets. Subsequently, an antireflective (AR) film was attached to each substrate (PET film) via an adhesive sheet. After that, each liquid crystal display was set to display black, and the display screen was visually observed for assessment of invisibility. Assessment criteria for invisibility are described below.

Assessment Criteria for Invisibility

AA: Any pattern is not visually recognized from any angle.

A: The pattern is very difficult to visually recognize but may be visible depending on angles.

C: The pattern is visible.

TABLE 1

| | | | | | | | | |
|---|---|---|---|---|---|---|---|---|
| Ag 1 | Lengths of silver nanowires | 1-5 | 6-10 | 11-20 | 21-30 | 31-40 | 41-50 | >51 |
| | (μm) | | | | | | | |
| | Presence percentage | 25.7% | 22.5% | 27.8% | 18.2% | 4.8% | 1.1% | 0.0% |
| Ag 2 | Lengths of silver nanowires | 1-5 | 6-10 | 11-20 | 21-30 | 31-40 | 41-50 | >51 |
| | (μm) | | | | | | | |
| | Presence percentage | 0.0% | 12.0% | 20.0% | 24.0% | 32.0% | 10.0% | 2.0% |
| Ag 3 | Lengths of silver nanowires | <30 | 31-40 | 41-50 | 51-60 | 61-70 | 71-80 | 81< |
| | (μm) | | | | | | | |
| | Presence percentage | 17.0% | 14.0% | 27.0% | 21.0% | 14.0% | 5.0% | 2.0% |
| Ag 4 | Lengths of silver nanowires | <50 | 51-100 | 101-150 | 151-200 | 201-250 | 251-300 | 300< |
| | (μm) | | | | | | | |
| | Presence percentage | 19.0% | 29.0% | 41.0% | 11.0% | 0.0% | 0.0% | 0.0% |
| Agnws-L50 | Lengths of silver nanowires | <50 | 51-100 | 101-150 | 151-200 | 201-250 | 251-300 | 300< |
| | (μm) | | | | | | | |
| | Presence percentage | 7% | 7% | 18% | 33% | 28% | 7% | 0% |
| Ag 5 | Lengths of silver nanowires | <1 | 1-2 | 2-3 | 3-4 | 4-5 | 5-6 | 6< |
| | (μm) | | | | | | | |
| | Presence percentage | 13.0% | 14.0% | 18.0% | 16.0% | 20.0% | 14.0% | 5.0% |

TABLE 2

| | | Average | | | A) | | C) |
|---|---|---|---|---|---|---|---|
| | Metal | length | Diameter | | Total light | B) | Sheet |
| | nanowire | (μm) | (mm) | Colored compound | transmittance | Haze value | resistance |
| Example 1 | Ag 1 | 10 | 30 | Lanyl Black BG E/C | 91.2 | 0.9 | 100 |
| Example 2 | Ag 1 | 10 | 30 | DEN | 90.8 | 1.0 | 100 |
| Example 3 | Ag 1 | 10 | 30 | LAI920 | 90.9 | 0.9 | 120 |
| Example 4 | Ag 1 | 10 | 30 | Lanyl Black BG E/C | 91.2 | 1.0 | 100 |
| Example 5 | Ag 1 | 10 | 30 | Lanyl Black BG E/C | 91.0 | 1.1 | 100 |
| Example 6 | Ag 1 | 10 | 30 | Lanyl Black BG E/C | 90.6 | 1.4 | 110 |
| Example 7 | Ag 2 | 30 | 50 | Lanyl Black BG E/C | 90.9 | 0.9 | 100 |
| Example 8 | Ag 3 | 50 | 50 | Lanyl Black BG E/C | 90.1 | 1.1 | 100 |
| Example 9 | Ag 1 | 10 | 30 | None | 90.8 | 1.0 | 100 |
| Comparative Example 1 | Ag 4 | 100 | 60 | Lanyl Black BG E/C | 91.6 | 1.4 | 160 |
| Comparative Example 2 | Agnws-L50 | 200 | 50 | Lanyl Black BG E/C | 91.4 | 1.3 | 140 |
| Example 10 | Ag 5 | 3 | 30 | Lanyl Black BG E/C | 91.3 | 0.9 | Unmeasurable |

| | D) | E) | F) Resolution | | | | | | |
|---|---|---|---|---|---|---|---|---|---|
| | Reflectance | Adhesion | Distance between electrodes (μm) | | | | | | G) |
| | L value | properties | 100 | 50 | 25 | 12 | 6 | 3 | Invisibility |
| Example 1 | 8.4 | 100/100 | AA | AA | AA | C | C | C | AA |
| Example 2 | 8.8 | 100/100 | AA | AA | AA | C | C | C | A |
| Example 3 | 8.6 | 100/100 | AA | AA | AA | C | C | C | AA |
| Example 4 | 8.5 | 100/100 | AA | AA | AA | C | C | C | AA |
| Example 5 | 8.6 | 100/100 | AA | AA | A | C | C | C | AA |
| Example 6 | 9.1 | 100/100 | AA | AA | A | C | C | C | AA |
| Example 7 | 8.5 | 100/100 | AA | AA | A | C | C | C | AA |
| Example 8 | 8.5 | 100/100 | AA | A | C | C | C | C | AA |
| Example 9 | 8.8 | 100/100 | AA | AA | AA | C | C | C | C |
| Comparative Example 1 | 9.6 | 100/100 | C | C | C | C | C | C | |
| Comparative Example 2 | 9.5 | 100/100 | C | C | C | C | C | C | |
| Example 10 | 8.6 | 100/100 | AA | AA | AA | AA | A | C | AA |

It can be seen from Table 1 that, whether used for forming transparent electrodes having a distance between the electrodes of 20 μm or a distance between the electrodes of 40 μm, 60% or less of the total number of the metal nanowires Ag 1 are those having lengths greater than 0.5 times the distance between the electrodes. On the other hand, supposing that the metal nanowires Ag 2 are used for forming transparent electrodes having a distance between the electrodes of 40 μm, greater than 60% of the total number of the metal nanowires Ag 2 are those having lengths greater than 0.5 times the distance between the electrodes. This indicates superiority of Ag 1 over Ag 2 for the formation of transparent electrodes having the distance between the electrodes of 40 μm.

It can also be seen, for each of Ag 1 and Ag 2, that 50% or less of the total number of the metal nanowires are those having lengths of 5 μm or less.

Furthermore, Table 2 indicates the following. Firstly, each Example exhibits good resolutions in patterns having distances between the electrodes of 20 μm or more and also exhibits good visibility.

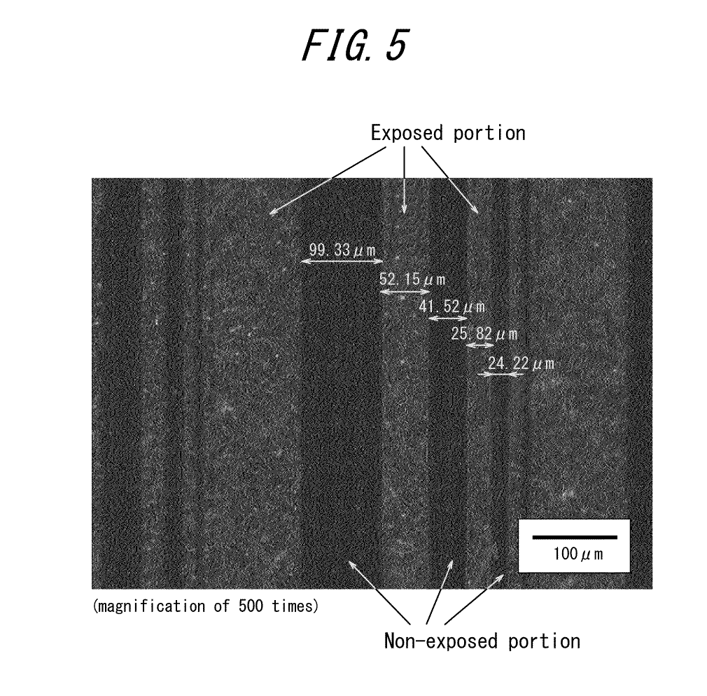

As a representative example, an optical micrograph of Example 1 is shown in FIG. 5 (at a magnification of 500 times). The tolerance ranges with respect to the resolution of Example 5, when having a distance between the electrodes of 25 μm, were within ±20%. The reason is probably that light slightly leaked to the non-exposed portion or that the reaction propagated during irradiation at the cumulative light quantity of 5000 mJ.

Regarding the pattern with a distance between the electrodes of 25 μm, Comparative Example 1, with the metal nanowires having an average length of greater than 50 μm and 1.5 times or less the distance between the electrodes, exhibits an insufficient resolution, whereas Example 7, with the metal nanowires having an average length of from 5 μm to 50 μm and 1.5 times or less the distance between the electrodes, exhibits a satisfactory resolution, and moreover, Example 4, with the metal nanowires having an average length of 1.2 times or less the distance, exhibits an even better resolution.

Regarding the pattern with a distance between the electrodes of 100 μm, Comparative Example 1 exhibits an insufficient resolution because Comparative Example 1 contains the metal nanowires having an average length of 100 μm, which, although being 1.5 times or less the distance between the electrodes, is greater than 50 μm. Comparative Example 2, with the metal nanowires having an average length of greater than 50 μm, exhibits an insufficient resolution.

Example 9 had a worse visibility than the aforementioned Example 1. The reason is probably that the surfaces of the silver nanowires were not coated with any colored compound.

### REFERENCE SIGNS LIST

1 . . . Transparent conductive element
11 . . . Transparent substrate
12 . . . Film
13 . . . Transparent electrode

1. An ink composition for forming a transparent conductive film used for transparent electrodes having a distance between the electrodes of 20 μm or more, the ink composition containing: metal nanowires; a photosensitive material; and a solvent, wherein the metal nanowires have an average length of 1.5 times or less the distance between the electrodes.

2. The ink composition for forming the transparent conductive film of claim 1, wherein the average length of the metal nanowires is in the range from 5 μm to 50 μm.

3. An ink composition for forming a transparent conductive film used for transparent electrodes having a distance between the electrodes of less than 20 μm, the ink composition containing: metal nanowires; a photosensitive material; and a solvent, wherein the metal nanowires have an average length of 5 μm or more and 0.5 times or less the distance between the electrodes.

4. The ink composition for forming the transparent conductive film of claim 1, wherein the photosensitive material includes a compound containing at least one of an azide group and a diazirine group.

5. The ink composition for forming the transparent conductive film of claim 1, wherein 60% or less of a total number of the metal nanowires comprise metal nanowires having lengths greater than 0.5 times the distance between the electrodes.

6. The ink composition for forming the transparent conductive film of claim 1, wherein 50% or less of a total number of the metal nanowires comprise metal nanowires having lengths of 5 μm or less.

7. The ink composition for forming the transparent conductive film of claim 1, wherein the metal nanowires have an average diameter in the range from 1 nm to 500 nm.

8. The ink composition for forming the transparent conductive film of claim 1, wherein the metal nanowires have an aspect ratio (average length/average diameter) in the range from 10 to 50000.

9. The ink composition for forming the transparent conductive film of claim 1, wherein the metal nanowires comprise at least one metal selected from the group consisting of Ag, Au, Ni, Cu, Pd, Pt, Rh, Ir, Ru, Os, Fe, Co, and Sn.

10. An ink composition for forming a transparent conductive film used for transparent electrodes, the ink composition containing: metal nanowires; a photosensitive material; and a solvent, wherein the photosensitive material includes a compound containing at least one of an azide group and a diazirine group.

11. The ink composition for forming the transparent conductive film of claim 10, wherein the photosensitive material includes a polymer containing, in at least one of a main chain and a side chain thereof, at least one of the azide group and the diazirine group.

12. The ink composition for forming the transparent conductive film of claim 11, wherein the polymer containing, in at least one of the main chain and the side chain thereof, at least one of the azide group and the diazirine group is of the following general formula (I): 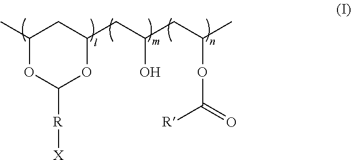
wherein, X represents one or more photosensitive groups containing at least one of the azide group and the diazirine group; R represents one of a chain or cyclic alkylene group and a derivative thereof and may contain, in at least one of a main chain and a side chain thereof, one or more of an unsaturated bond, an ether bond, a carbonyl bond, an ester bond, an amide bond, an urethane bond, a sulfide bond, an aromatic ring, a heterocyclic ring, an amino group, and a quaternary ammonium base; R′ represents one of a chain or cyclic alkyl group and a derivative thereof and may contain, in at least one of a main chain and a side chain thereof, one or more of an unsaturated bond, an ether bond, a carbonyl bond, an ester bond, an amide bond, an urethane bond, a sulfide bond, an aromatic ring, a heterocyclic ring, an amino group, and a quaternary ammonium base; and 1 is 1 or more, m is 1 or more, and n is 0 or more.

13. The ink composition for forming the transparent conductive film of claim 10, wherein the photosensitive material contains a binder resin, and a crosslinker containing at least one of the azide group and the diazirine group.

14. The ink composition for forming the transparent conductive film of claim 13, wherein the binder resin comprises a water-soluble polymer.

15. The ink composition for forming the transparent conductive film of claim 1, further containing: a colored compound.

16. An ink composition for forming a transparent conductive film used for transparent electrodes having a distance between the electrodes of 20 μm or more, the ink composition containing: metal nanowires; a photosensitive material; and a solvent, wherein the metal nanowires have an average length of 1.5 times or less the distance between the electrodes,
the photosensitive material includes a polymer containing, in at least one of a main chain and a side chain thereof, at least one of an azide group and a diazirine group, and
the polymer containing, in at least one of the main chain and the side chain thereof, at least one of the azide group and the diazirine group is of the following general formula (I): 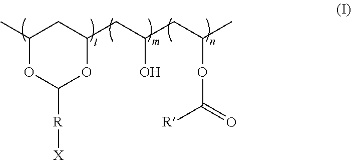
wherein, X represents one or more photosensitive groups containing at least one of the azide group and the diazirine group; R represents one of a chain or cyclic alkylene group and a derivative thereof and may contain, in at least one of a main chain and a side chain thereof, one or more of an unsaturated bond, an ether bond, a carbonyl bond, an ester bond, an amide bond, an urethane bond, a sulfide bond, an aromatic ring, a heterocyclic ring, an amino group, and a quaternary ammonium base; R′ represents one of a chain or cyclic alkyl group and a derivative thereof and may contain, in at least one of a main chain and a side chain thereof, one or more of an unsaturated bond, an ether bond, a carbonyl bond, an ester bond, an amide bond, an urethane bond, a sulfide bond, an aromatic ring, a heterocyclic ring, an amino group, and a quaternary ammonium base; and 1 is 1 or more, m is 1 or more, and n is 0 or more.

17. The ink composition for forming the transparent conductive film of claim 16, further containing: a colored compound.

18. A transparent conductive film, comprising a cured product of the ink composition for forming the transparent conductive film of claim 15, wherein the colored compound is substantially adsorbed to the metal nanowires.

19. The transparent conductive film of claim 18, wherein a content of the colored compound unadsorbed to the metal nanowires is in the range from 0.05 to 9.9 weight % of the transparent conductive film.

20. A method for producing transparent electrodes having a predetermined distance between the electrodes, the method comprising: forming, on a substrate, a film of the ink composition for forming the transparent conductive film of claim 1; pattern exposing the formed film; and developing the pattern exposed film.

21. The method for producing the transparent electrodes of claim 20, further comprising: calendering the developed film.

22. An image display device, comprising: an image display panel; and electrodes formed on a display surface side of the image display panel and by using a transparent conductive film, wherein the transparent conductive film comprises a cured product of the ink composition for forming the transparent conductive film of claim 1.

23. The image display device of claim 22, further comprising: a touch panel formed by using the transparent conductive film comprising the cured product of the ink composition for forming the transparent conductive film of claim 1.
